(19) United States
(12) Patent Application Publication
(10) Pub. No.: US 2013/0207137 A1
(43) Pub. Date: Aug. 15, 2013

(54) COB-Typed LED Light Board

(71) Applicant: Yu-Mei LEE, Xinbei City (TW)

(72) Inventor: Yu-Mei LEE, Xinbei City (TW)

(73) Assignee: POLAR-LIGHTS OPTO CO., LTD., Xinbei City (TW)

(21) Appl. No.: 13/557,368

(22) Filed: Jul. 25, 2012

(30) Foreign Application Priority Data
Feb. 15, 2012 (TW) 101104882

(51) Int. Cl. H01L 25/13

(52) U.S. Cl. 257/89; 257/E25.028

(57) ABSTRACT

A COB-typed LED light board for providing mixing light includes a substrate and a plurality of COB light bodies. The COB light bodies, which are provided on a mounting surface of the substrate, emit light with two or more different spectrums. A space distance between the adjacent two LED chips is smaller than 20 mm and is larger than a width of a single LED chip, the outer surface of a glue body which does not contact the mounting surface is provided to contact external atmosphere, and a middle portion of the glue body, formed by cohesion, is higher than a periphery portion thereof, to thus have the COB light bodies with excellent heat dissipation and an even mixing light.

### FIELD OF THE INVENTION

The present invention relates to a LED light board, and more particularly to a COB-typed LED light board.

### BACKGROUND OF THE INVENTION

Recently, light emitting diodes (LEDs) have gradually replaced the traditional lighting elements due to the characteristic of small size, fast response, long life, low attenuation, firm structure, anti-knocking, whole light color (including invisible light), orientation, low voltage demand, low current demand, low transition loss, low heat radiation, easy production, environmental protection, and so on.

There refers LED device as a device in which a series of LED light elements are connected in series and the LED light elements are disposed on a circuit board such as a light board. And, there are various methods for manufacturing LED devices, including chip on board (COB) technology, as an example. COB process is a process in which wire attaching and glue sealing are applied to a field of printed circuit board (PCB). Further, a COB light refers to a semiconductor assembly formed by mounting a chip or die directly on the circuit board, electrically connecting a wire between the chip and the circuit board, and covering the chip and the wire with glue. The COB technology saves heavy steps in traditional IC packaging technology to gain an advantage of lower cost.

### SUMMARY OF THE INVENTION

However, in a conventional COB-typed LED light board, it must provide side frames (glue frames) to surround all chips on the circuit board and package all the surrounded chips by covering the same glue to form a plane-type package body. The same material of covering glue limits the light from each light element on the circuit board to have the same lighting characteristic and its emitting angle in plane, so that a desired light having specific spectrum and emitting angle according to demands of different application fields is hard to be provided.

Therefore, it is an object of the present invention to provide a COB-typed LED light board in which lighting characteristic of every point of light thereof can be designated, so as to satisfy demands of light in different application fields.

The present invention overcomes the drawbacks of the prior art, and provides a COB-typed LED light board for providing mixing light, comprising: a substrate, having a mounting surface; and a plurality of COB light bodies, each COB light body being formed by covering glue body on at least one LED chip which is provided on the mounting surface of the substrate, by which the COB light body emits light with two or more different spectrums, wherein a space distance between the adjacent two LED chips is smaller than 20 mm and is larger than a width of a single LED chip, the outer surface of the glue body, which does not contact the mounting surface, is provided to contact external atmosphere, and a middle portion of the glue body, formed by cohesion, is higher than a periphery portion thereof.

In an embodiment of the present invention, a light wavelength of the LED chip is selected from the group of ultraviolet light of 200-410 nm, blue light of 410-500 nm, green light of 500-570 nm, yellow light of 570-580 nm, amber light of 580-590 nm, red light of 590-650 nm, deep red light of 650-680 nm, and infrared light of 680-960 nm.

In an embodiment of the present invention, at least one type of phosphor is added into a part or all of the COB light bodies.

In an embodiment of the present invention, a light wavelength of said phosphor is selected from the group of x=0.09-0.17, x=0.17-0.38, x=0.38-0.54, and x=0.54-0.75 in the CIE 1931 XYZ color space.

In an embodiment of the present invention, the glue body is formed of silicon, epoxy, acrylic, glass, or plastic.

In an embodiment of the present invention, the outer surface of the glue body is a curved surface.

In an embodiment of the present invention, the COB light bodies are arranged in a line or a plane.

In an embodiment of the present invention, the COB light body is further includes an outer glue body cover the glue body, and a middle portion of the outer glue body is higher than a periphery portion of the outer glue body.

Thereby, the lighting characteristic of individual point of light element on the COB-typed LED light board can be designated. By controlling the lighting characteristics of every point of light, the wavelength distribution and the intensity of the wavelength can be precisely adjusted to form a mixing light having suitable light color, color temperature, spectrum, and intensity of wavelength corresponding to demands of different application fields.

### BRIEF DESCRIPTION OF THE DRAWINGS

The structure and the technical means adopted by the present invention to achieve the above and other objects can be best understood by referring to the following detailed description of the preferred embodiments and the accompanying drawings.

FIG. 1 is a side view of a COB-typed LED light board according to an embodiment of the present invention;

FIG. 2 is a top view of the COB-typed LED light board according to the embodiment of the present invention;

FIG. 3 is an enlarged drawing of the COB-typed LED light board according to the embodiment of the present invention;

FIG. 4 is a cross-sectional view of the COB-typed LED light board according to another embodiment of the present invention; and

FIG. 5 is a flow chart of a method of manufacturing the COB-typed LED light board according to the embodiment of the present invention.

### DETAILED DESCRIPTION OF THE PREFERRED EMBODIMENTS

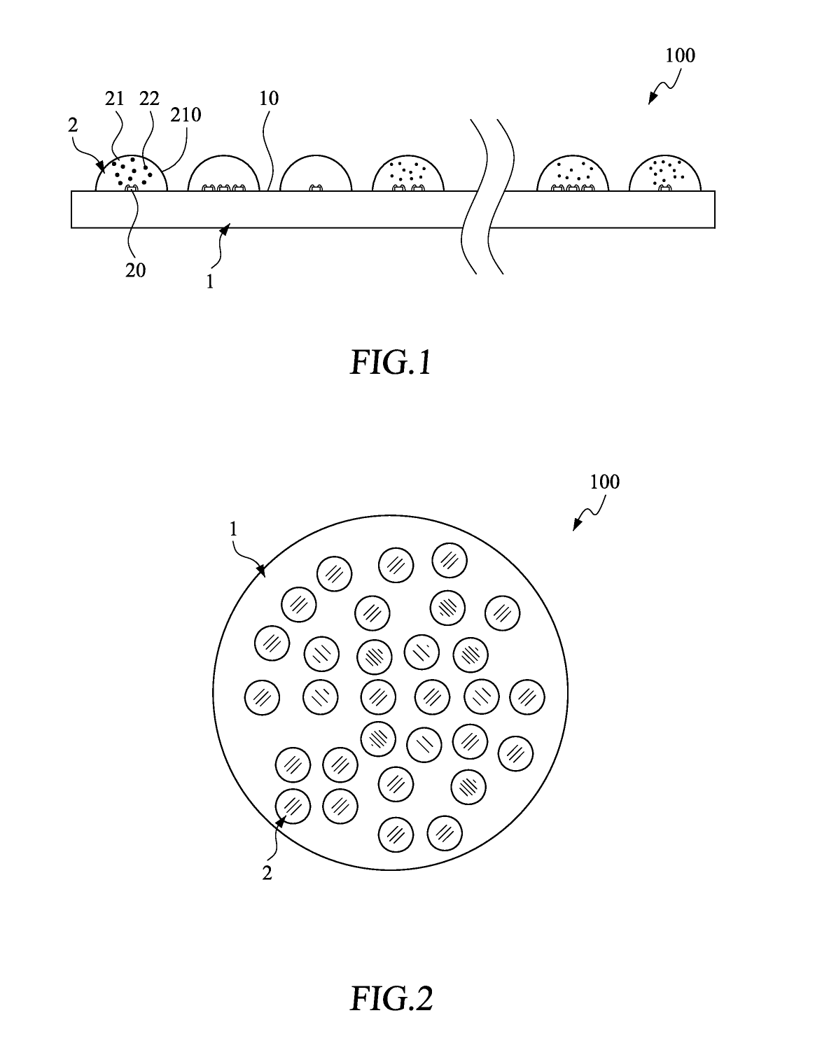

Please refer to FIGS. 1 and 2. FIG. 1 is a side view of a COB-typed LED light board according to an embodiment of the present invention, and FIG. 2 is a top view of the COB-typed LED light board according to the embodiment of the present invention.

As shown in FIGS. 1 and 2, a COB-typed LED light board 100 according to an embodiment of the present invention includes a substrate 1 and a plurality of COB light bodies 2. The substrate 1 has a mounting surface 10, and the COB light bodies 2 are formed on the mounting surface 10 of the substrate 1. The COB light body 2 is a light body formed on the mounting surface 10 of the substrate 1 by covering at least one LED chip 20 mounted on the substrate 1 with a glue body 21.

For the COB-typed LED light board 100, the LED chip 20 of the light bodies 2 having the same or different light wavelength can be used. For example, the light wavelength can be selected from ultraviolet light of 200-410 nm, blue light of 410-500 nm, green light of 500-570 nm, yellow light of 570-580 nm, amber light of 580-590 nm, red light of 590-650 nm, deep red light of 650-680 nm, and infrared light of 680-960 nm. Further, the number of the LED chips 20 of COB light bodies 2 can be different and the light wavelength of the LED chips 20 in the same COB light body 2 also can be different.

In addition, the glue body 21 of the COB light body 2 may be a transparent glue body or a colored glue body. And, the glue body 21 may be made of silicon, epoxy, acrylic, glass, or plastic.

Further, one or more types of phosphors 22 may be provided in the COB light bodies 2. The light wavelength of the phosphors may be selected from the group of x=0.09-0.17, x=0.17-0.38, x=0.38-0.54, and x=0.54-0.75 in the CIE 1931 XYZ color space.

Therefore, the lighting characteristics of the COB light bodies 2 can be designated respectively by permutations and combination of the LED chip 20, the glue body 21, and the phosphors 22 for emitting a light having a specific spectrum. Thus, a plurality of COB light bodies 2 can emit totally two or more types of light with different spectrum.

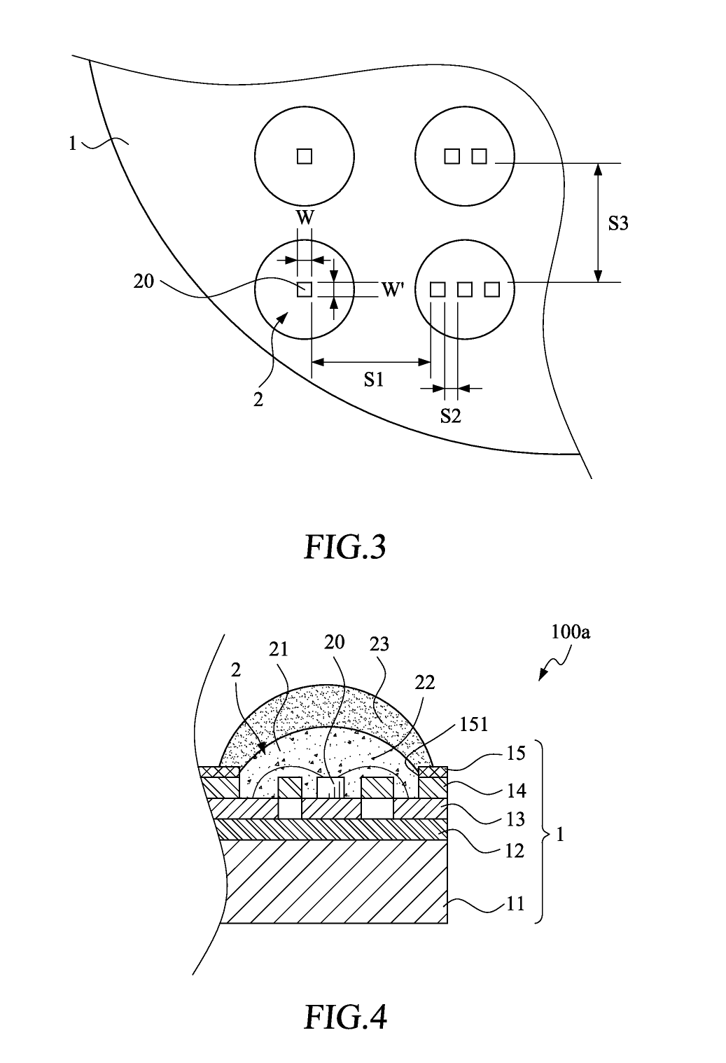

Please refer to FIG. 3, which is an enlarged drawing of the COB-typed LED light board according to the embodiment of the present invention. The COB light bodies 2 on the substrate 1 can be provided in any arrangements such as along a line or in a plane. For having the COB light bodies 2 with excellent heat dissipation and an even mixing light, the LED chips 20 must be adjusted to have a suitable distance therebetweeen. If the distance between the LED chips 20 is too small, the heat generated from the LED chips 20 is difficult to be dissipated, and thus the luminous efficacy is lowered. If the distance between the LED chips 20 is too large, it can not have enough overlap between the illuminating areas of the LED chips 20, and it is difficult to obtain an even mixing light having desired spectrum. For the reason, in the present invention, a condition for a suitable distance is set according to a spreading resistance relation. The condition refers that a space distance between the adjacent two LED chips should be smaller than 20 mm and be larger than a width of a single LED chip. For example, in the case that the LED chip 20 has a lateral width of W and a longitudinal width of W′, a lateral space distance (S1) between LED chips 20 of different COB light bodies 2 should satisfy the function of W<51<20 mm, a lateral space distance (S2) between LED chips 20 of one COB light body 2 should satisfy the function of W<S2<20 mm, and a longitudinal space distance (S3) between LED chips 20 of different COB light bodies 2 should satisfy the function of W′<S3<20 mm. Under the condition, the COB light bodies 2 can be adjusted to have a suitable distance therebetween to obtain excellent heat dissipation effect and form an even mixing light by overlapping of the emitted light.

Referring back to FIG. 1, for providing a precisely mixing light having desired spectrum, it is preferable to designate the individual COB light body 2 to have a specific emitting angle as well as the space distance. In the present invention, the outer surface 210 of the glue body 21 which does not contact the substrate 1 is provided to contact external atmosphere, and a middle portion of the glue body 21, formed by cohesion, is higher than a periphery portion thereof. Specifically, an outer surface 210 of the glue body 21 is an arc surface. The emitting angle of the COB bodies 2 are set respectively by adjusting the curvature of the outer surface 210 of the glue body 21. In addition, referring to FIG. 4, which is a cross-sectional view of the COB-typed LED light board 100a according to another embodiment of the present invention, an outer glue body 23 covering the glue body 21 is further provided. A middle portion of the outer glue body 23 is higher than a periphery portion of the outer glue body 23, and thus the emitting angle can be further adjusted.

With the above structure, the emitting angle of COB light body 2 can be adjusted corresponding to different light color without being limited the emitting angle in plane. Further, because the glue body 21 is formed with an arc surface by cohesion without using glue frames, the structure is simpler. Moreover, after forming the COB light body 2, it is not only no need to perform any subsequent process (e.g. cutting) but also no need to provide a lens. Thus, the manufacturing processes can be simplified and additional parts can be decreased, and thus the production capacity and the product competitiveness are improved.

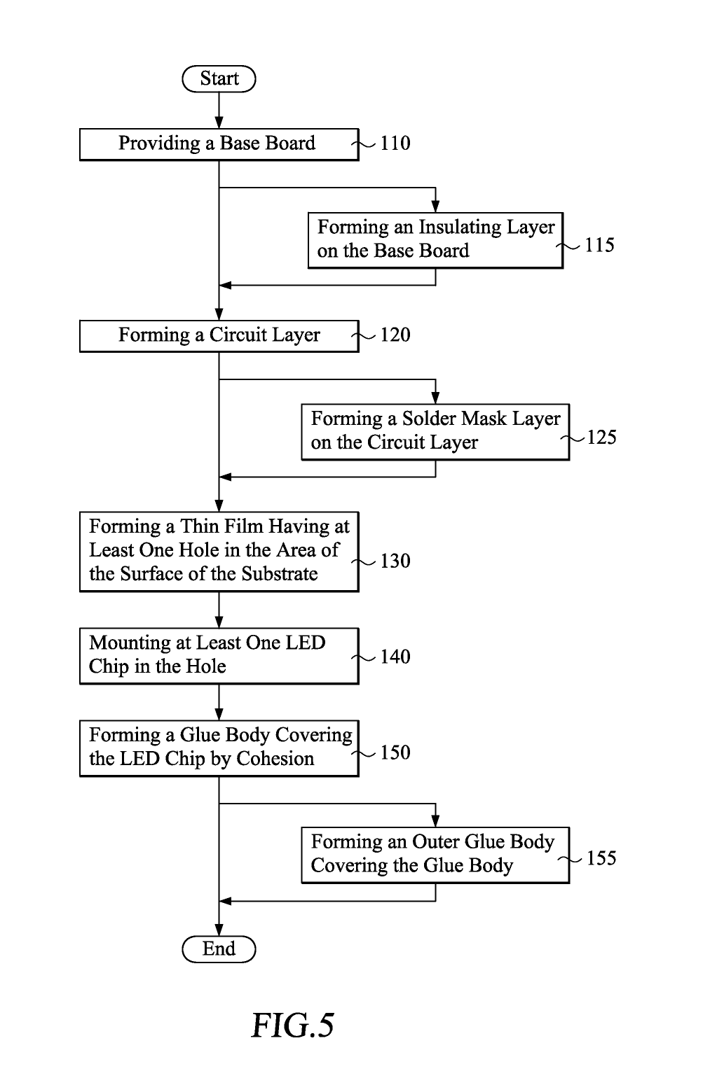

The method of manufacturing the COB-typed LED light board according to the embodiment of the present invention will be described here with reference to FIG. 5 and FIG. 4. First, providing a base board 11 (step 110). As the base board 11, a non-conductive material such as aluminum and copper or a conductive material such as graphite, diamond, silicon, and glass fiber can be used. In the case that the base board 11 is made of a conductive material, forming an insulating layer 12 on the base board 11 (step 115). The insulating layer 12 is used for insulating the base board 11 from a circuit layer 13 to be formed, so as to prevent electric influence from the circuit layer 13. In the case of the base board 11 is made of a non-conductive material, the insulating layer 12 is provided on the base board 11 selectively.

Next, forming a circuit layer 13 on the base board 11 (or on the insulating layer 12). The circuit layer 13 is a conductive layer containing silver, copper, or silver paste and having a circuit pattern for mounting LED chips thereon. Preferably, a solder mask layer 14 may be formed on the circuit layer 13 (step 125). The solder mask layer 14 is a non-conductive layer for protecting the circuit pattern of the circuit layer 13 and preventing parts from being soldered to an unexpectedly location. A screen printed layer (not shown) is sometimes formed on the solder mask layer 14 to mark symbols at mounting locations for parts.

Next, forming a thin film 15 on the circuit layer 13 (or the solder mask layer 14) (step 130). In detail, thin film 15, which is provided with 0.005-0.1 mm in thickness, is not like the glue frame having thickness in several millimeters. It is preferred to form the thin film 15 by the ways in the order of printing, exposing, developing, and the like for the purpose of fast and convenient for adjusting, but another way also may be used. The thin film 15 is provided with at least one hole 151 at one or more place in the area of the surface of the substrate 1.

Next, at least one LED chip 20 is in each hole 151 (step 140). And, the LED chip 20 is electrically connected with the circuit layer 13 through wires (gold, silver, copper, or alloy wires). After mounting the LED chip 20, a glue body 21 is formed to covering all of the LED chips 20 in the same hole 151 (step 150). A middle portion of the glue body 21, formed by cohesion, is higher than a periphery portion thereof, so that the glue body 21 has a curved shape in a cross-section view. One or more type of phosphors may be selectively added into the glue body 21. Further, after forming the glue body 21, the outer glue body 23 may be formed to cover the glue body 21 to adjust the emitting angle.

Thereby, the lighting characteristic of individual point of light element (COB light body 2) on the COB-typed LED light board 100 can be designated. By controlling the lighting characteristics of every point of light, the wavelength distribution and the intensity of the wavelength can be precisely adjusted to form a mixing light having suitable light color, color temperature, spectrum, and intensity of wavelength corresponding to demands of different application fields.

As can be appreciated from the above embodiments, the COB-typed LED light board of the present invention has industry worth which meets the requirement for a patent. The above description should be considered as only the discussion of the preferred embodiments of the present invention. However, a person having ordinary skill in the art may make various modifications to the present invention. Those modifications still fall within the spirit and scope defined by the appended claims.

What is claimed is:

1. A COB-typed LED light board for providing mixing light, comprising:
a substrate, having a mounting surface; and
a plurality of COB light bodies, each COB light body being formed by covering glue body on at least one LED chip which is provided on the mounting surface of the substrate, by which the COB light body emits light with two or more different spectrums,
wherein a space distance between the adjacent two LED chips is smaller than 20 mm and is larger than a width of a single LED chip, the outer surface of the glue body which does not contact the mounting surface is provided to contact external atmosphere, and a middle portion of the glue body, formed by cohesion, is higher than a periphery portion thereof.

2. The COB-typed LED light board as claimed in claim 1, wherein a light wavelength of the LED chip is selected from the group of ultraviolet light of 200-410 nm, blue light of 410-500 nm, green light of 500-570 nm, yellow light of 570-580 nm, amber light of 580-590 nm, red light of 590-650 nm, deep red light of 650-680 nm, and infrared light of 680-960 nm.

3. The COB-typed LED light board as claimed in claim 1, wherein at least one type of phosphor is added into a part or all of the COB light bodies.

4. The COB-typed LED light board as claimed in claim 3, wherein a light wavelength of the phosphor is selected from the group of x=0.09-0.17, x=0.17-0.38, x=0.38-0.54, and x=0.54-0.75 in the CIE 1931 XYZ color space.

5. The COB-typed LED light board as claimed in claim 1, wherein the glue body is formed of silicon, epoxy, acrylic, glass, or plastic.

6. The COB-typed LED light board as claimed in claim 1, wherein the outer surface of the glue body is a curved surface.

7. The COB-typed LED light board as claimed in claim 1, wherein the COB light bodies are arranged in a line or a plane.

8. The COB-typed LED light board as claimed in claim 1, wherein the COB light body is further includes an outer glue body cover the glue body, and a middle portion of the outer glue body is higher than a periphery portion of the outer glue body.
